(19) United States
(12) Patent Application Publication
(10) Pub. No.: US 2009/0134914 A1
(43) Pub. Date: May 28, 2009

(54) LOW OFFSET COMPARATOR AND OFFSET CANCELLATION METHOD THEREOF

(75) Inventor: Chih-Haur HUANG, Tainan County (TW)

Correspondence Address: RABIN & Berdo, PC, 1101 14TH STREET, NW, SUITE 500, WASHINGTON, DC, 20005, US

(73) Assignee: HIMAX TECHNOLOGIES LIMITED, Tainan County (TW)

(21) Appl. No.: 11/945,797

(22) Filed: Nov. 27, 2007

(51) Int. Cl. H03K 5/22

(52) U.S. Cl. 327/64

(57) ABSTRACT

A low offset comparator includes a preamplifier and a latch. The preamplifier includes a first output offset storage stage, a cascade of input offset storage stages and a second output offset storage stage. The first output offset storage stage receives an input voltage. The cascade of input offset storage stages is connected to follow the first output offset storage stage. The second output offset storage stage is connected to follow the input offset storage stages. The latch is connected to follow the preamplifier. The low offset comparator is characterized in that the cascade of input offset storage stages, the second output offset storage stage and the first output offset storage stage are configured to sequentially leave an offset cancellation mode, and the input offset storage stages, when leaving the offset cancellation mode, are to open their unity-gain feedback loops before disconnecting their input offset storages from a ground voltage.

### BACKGROUND OF THE INVENTION

1. Field of the Invention

The invention relates in general to a low offset comparator and an offset cancellation method thereof, and more particularly to a low offset comparator, which is capable of eliminating offset voltages more effectively and has a high circuit operation speed, and an offset cancellation method thereof.

2. Description of the Related Art

In a comparator, even a little noise may influence a circuit operation result. Due to the element mismatch, the comparator generates offset voltages when it performs an amplification operation. So, the offset cancellation technology has to be adopted for the purpose of compensation. The frequently used offset cancellation technology includes an input offset storage (IOS) and an output offset storage (OSS).

FIG. 1 (PRIOR ART) is a circuit diagram showing a conventional comparator 100 using the input offset storage technology. Referring to FIG. 1, the comparator 100 includes a preamplifier 110, a latch 120, input offset storages C1 and C2 and switches S1 to S6. The input offset storages C1 and C2 may be capacitors, for example. When the comparator 100 is in an offset cancellation mode, the switches S1 to S4 are turned on while the switches S5 and S6 are off. First ends of the input offset storages C1 and C2 are coupled to a ground voltage. At this time, a single gain feedback loop is created on the preamplifier 110. Thus, the input offset of the preamplifier 110 is stored in the input offset storages C1 and C2.

When the comparator 100 is in a tracking mode, the switches S1 to S4 are off while the switches S5 and S6 are turned on. At this time, the preamplifier 110 amplifies an input voltage Vin, and the input offsets stored in the input offset storages C1 and C2 are offset with the offset voltages generated by the comparator 100. Then, in a latching mode, the latch 120 is strobed by the amplified input voltage and outputs a logic level Vout accordingly. Because values of the input offset storages C1 and C2 have to be great enough to eliminate the offsets effectively, the implemented area circuit of the comparator 100 is enlarged, and the equivalent capacitor at the input end thereof is also very large.

FIG. 2 (PRIOR ART) is a circuit diagram showing a conventional comparator 200 using the output offset storage technology. Referring to FIG. 2, the comparator 200 includes a preamplifier 210, a latch 220, output offset storages C1 and C2 and switches S1 to S6. The output offset storages C1 and C2 may be capacitors, for example. When the comparator 200 is in an offset cancellation mode, the switches S1 to S4 are turned on, the switches S5 and S6 are off, first ends of the output offset storages C1 and C2 are coupled to a ground voltage and an input end of the preamplifier 210 is also coupled to the ground voltage. At this time, the output offset of the preamplifier 210 is stored in the output offset storages C1 and C2.

When the comparator 200 is in a tracking mode, the switches S1 to S4 are off and the switches S5 and S6 are turned on. At this time, the preamplifier 210 amplifies the input voltage Vin, and the output offsets stored in the output offset storages C1 and C2 are offset with the offset voltages generated by the comparator 200. Then, in a latching mode, the latch 220 is strobed by the amplified input voltage and outputs a logic level Vout accordingly. Because the input voltage Vin received by the comparator 200 is fed by way of DC coupling, the input range of the comparator 200 is smaller. In addition, a gain value A of the preamplifier 210 also cannot be too great. If the gain value A is too great, the amplified offset voltages may cause the preamplifier 210 to fail.

### SUMMARY OF THE INVENTION

The invention is directed to a low offset comparator and an offset cancellation method thereof, combining the input offset storage technology with the output offset storage technology so that the low offset comparator can eliminate offset voltages more effectively and have the higher circuit operation speed.

According to a first aspect of the present invention, a low offset comparator including a preamplifier and a latch is provided. The preamplifier includes a first output offset storage stage, a cascade of input offset storage stages and a second output offset storage stage. The first output offset storage stage receives an input voltage. The cascade of input offset storage stages is connected to follow the first output offset storage stage. The second output offset storage stage is connected to follow the input offset storage stages. The latch is connected to follow the preamplifier. The low offset comparator is characterized in that the cascade of input offset storage stages, the second output offset storage stage and the first output offset storage stage are configured to sequentially leave an offset cancellation mode, and the input offset storage stages, when leaving the offset cancellation mode, are to open their unity-gain feedback loops before disconnecting their input offset storages from a ground voltage.

According to a second aspect of the present invention, an offset cancellation method of a comparator is provided. The comparator includes a preamplifier that has a first output offset storage stage for receiving an input voltage, a cascade of input offset storage stages and a second output offset storage stage. The method includes the following steps. First, the cascade of input offset storage stages, the second output offset storage stage and the first output offset storage stage are configured to sequentially leave an offset cancellation mode. Afterwards, when leaving the offset cancellation mode, the input offset storage stages open their unity-gain feedback loops before disconnecting their input offset storages from a ground voltage

The invention will become apparent from the following detailed description of the preferred but non-limiting embodiments. The following description is made with reference to the accompanying drawings.

### BRIEF DESCRIPTION OF THE DRAWINGS

FIG. 1 (PRIOR ART) is a circuit diagram showing a conventional comparator using the input offset storage technology.

FIG. 2 (PRIOR ART) is a circuit diagram showing a conventional comparator using the output offset storage technology.

FIG. 3 is a circuit diagram showing a low offset comparator according to a preferred embodiment of the invention.

FIG. 4 shows a timing chart for the low offset comparator according to the preferred embodiment of the invention.

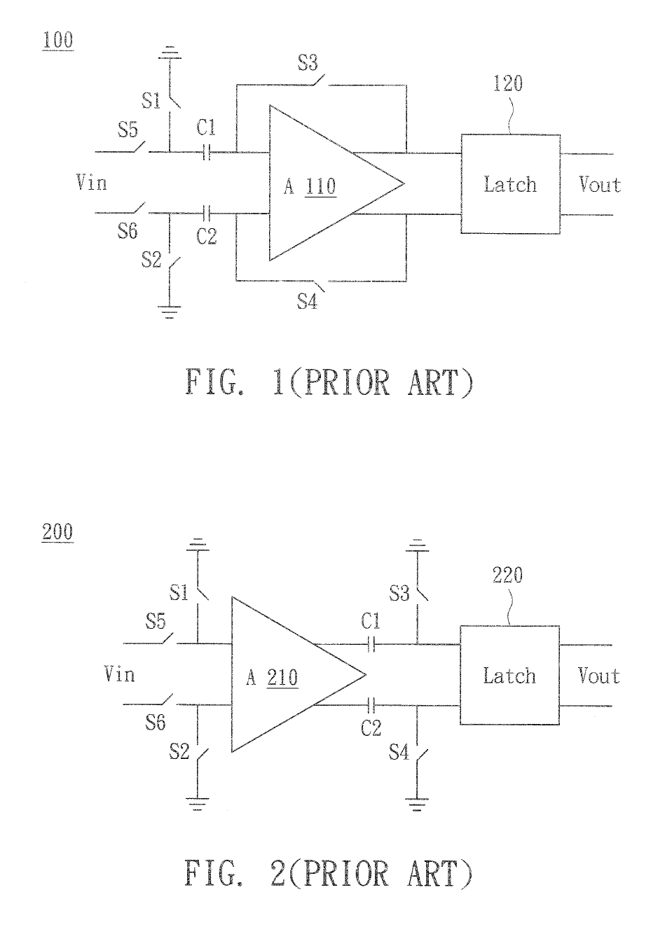

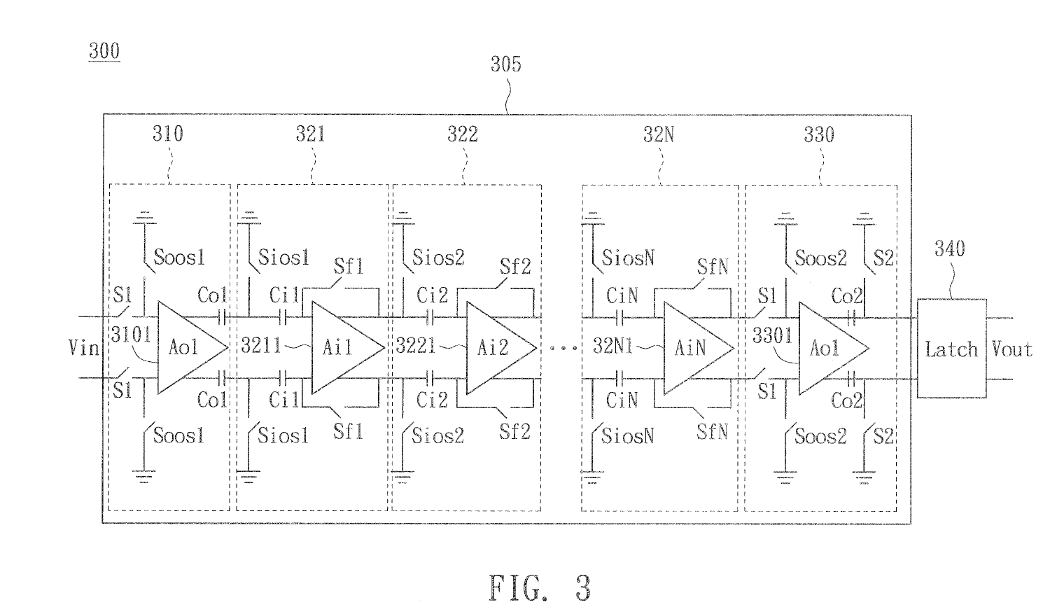

### DETAILED DESCRIPTION OF THE INVENTION

The invention provides a low offset comparator with a cascaded architecture combining the input offset storage technology with the output offset storage technology so that the low offset comparator can eliminate offset voltages more effectively, can have a higher circuit operation speed, and can be widely applied to various comparator circuits.

FIG. 3 is a circuit diagram showing a low offset comparator 300 according to a preferred embodiment of the invention. Referring to FIG. 3, the low offset comparator 300 includes a preamplifier 305 and a latch 340. The preamplifier 305 includes a first output offset storage stage 310, a cascade of N input offset storage stages 321 to 32N and a second output offset storage stage 330, wherein N is a positive integer. The first output offset storage stage 310 receives an input voltage Vin. The input offset storage stages 321 to 32N are sequentially coupled together in a cascaded manner and are connected to follow the first output offset storage stage 310. The input offset storage stage 321 is coupled to the first output offset storage stage 310.

The second output offset storage stage 330 is connected to follow the input offset storage stages 321 to 32N. The latch 340 is connected to follow the second output offset storage stage 330. First, in an offset cancellation mode, the N input offset storage stages 321 to 32N are sequentially to open their unity-gain feedback loops to store their input offsets to their input offset storages. Then, the second output offset storage stage 330 and the first output offset storage stage 310 respectively store their output offsets to their output offset storages.

Thereafter, in a tracking mode, the cascade of input offset storage stages 321 to 32N, the second output offset storage stage 330 and the first output offset storage stage 310 sequentially leave the offset cancellation mode. Then, the preamplifier 305 amplifies the input voltage Vin. The input offsets and the output offsets stored in the offset cancellation mode are respectively offset with offset voltages generated by the low offset comparator 300. Thereafter, in a latching mode, the latch 340 is strobed by the amplified input signal outputted from the preamplifier 305, and outputs a logic level Vout, which is a recognizable voltage level, accordingly.

The first output offset storage stage 310 includes a first rail-to-rail amplifier 3101, two first output offset storages Co1, two first output offset storage switches Soos1 and two first switches S1. The first rail-to-rail amplifier 3101 has two input ends and two output ends. The first output offset storages Co1, such as capacitors, have first ends respectively coupled to the output ends of the first rail-to-rail amplifier 3101, and second ends respectively coupled to the input offset storage stage 321. The first output offset storage switches Soos1 have first ends coupled to a ground voltage, and second ends respectively coupled to the input ends of the first rail-to-rail amplifier 3101. The first switches S1 have first ends for receiving the input voltage Vin, and second ends respectively coupled to the input ends of the first rail-to-rail amplifier 3101.

The input offset storage stages 321 to 32N have the same circuit architecture, so only the input offset storage stage 321 is illustrated. The input offset storage stage 321 includes an amplifier 3211, two input offset storages Ci1, two feedback switches Sf1 and two input offset storage switches Sios1. The amplifier 3211 has two input ends and two output ends. The input offset storages Ci1, such as capacitors, have second ends respectively coupled to the input ends of the amplifier 3211. The feedback switches Sf1 have first ends respectively coupled to the input ends of the amplifier 3211, and second ends respectively coupled to the output ends of the amplifier 3211. The input offset storage switches Sios1 have first ends coupled to the ground voltage, and second ends respectively coupled to the first ends of the input offset storages Ci1. In the input offset storage stages 321 to 32N, the second ends of the input offset storage switches Sios1 of the input offset storage stage 321 are respectively coupled to the first output offset storage stage 310.

The second output offset storage stage 330 includes a second rail-to-rail amplifier 3301, two second output offset storages Co2, two second output offset storage switches Soos2, two first switches S1 and two second switches S2. The second rail-to-rail amplifier 3301 has two input ends and two output ends. The second output offset storages Co2, such as capacitors, have first ends respectively coupled to the output ends of the second rail-to-rail amplifier 3301, and second ends respectively coupled to the latch 340.

The second output offset storage switches Soos2 have first ends coupled to the ground voltage, and second ends respectively coupled to the input ends of the second rail-to-rail amplifier 3301. The first switches S1 have first ends coupled to the output ends of the amplifier 32N1 of the input offset storage stage 32N, and second ends respectively coupled to the input ends of the second rail-to-rail amplifier 3301. The second switches S2 have first ends coupled to the ground voltage, and second ends respectively coupled to the latch 340.

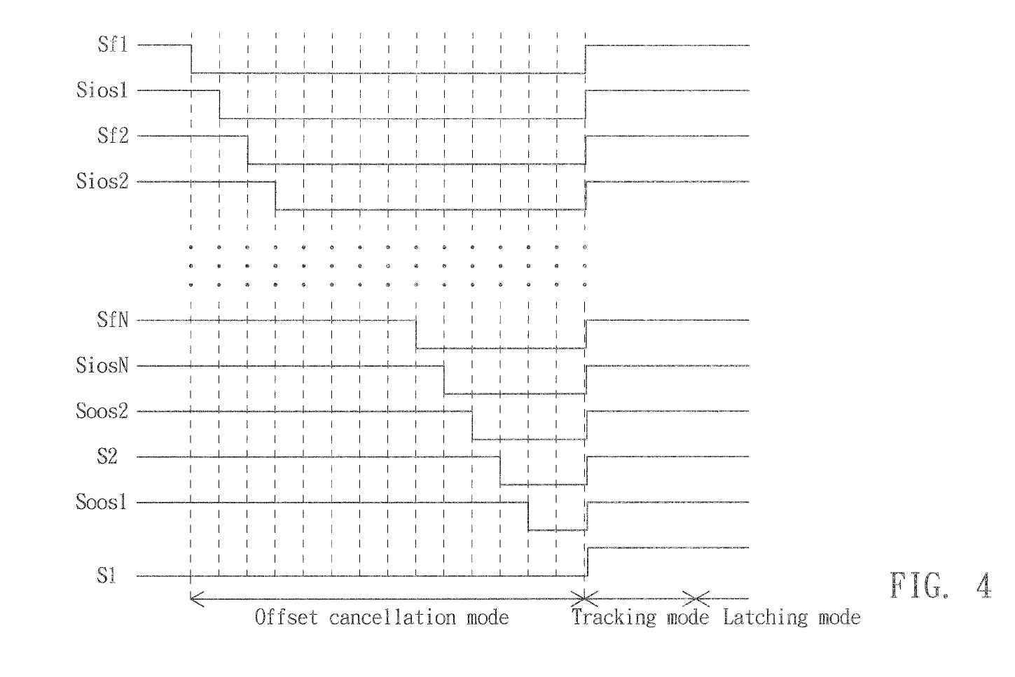

FIG. 4 shows a timing chart for the low offset comparator according to the preferred embodiment of the invention. As shown in FIG. 4, in the offset cancellation mode, the feedback switches Sf1 to SfN and the input offset storage switches Sios1 to SiosN of the input offset storage stages 321 to 32N are sequentially and alternately turned on according to the following order: the feedback switch Sf1->the input offset storage switch Sios1->the feedback switch Sf2->the input offset storage switch Sios2-> . . . ->the feedback switch SfN->the input offset storage switch SiosN. That is, the input offset storage stages 321 to 32N are sequentially to open their unity-gain feedback loops to store their input offsets to their input offset storages Ci1 to CiN.

Then, the second output offset storage switches Soos2 of the second output offset storage stage 330 are turned on. Next, the second switches S2 of the second output offset storage stage 330 are turned on. Thus, the output offsets of the second output offset storage stage 330 are stored in their output offset storages Co2. Thereafter, the first output offset storage switches Soos1 of the first output offset storage stage 310 are turned on. Thus, the output offsets of the first output offset storage stage 310 are stored in their output offset storages Co1. In this offset cancellation mode, the first switches S1 of the first output offset storage stage 310 and the second output offset storage stage 330 are off.

In the offset cancellation mode, N input offset storage circuits 321 to 32N sequentially store the corresponding input offsets to the input offset storages Ci1 to CiN, and the second output offset storage stage 330 and the first output offset storage stage 310 also sequentially store the corresponding output offsets to the first output offset storages Co1 and the second output offset storages Co2. Every two corresponding offset storages, such as two input offset storages Ci1, may have the same offset storage value or different offset storage values as long as the corresponding input offsets or output offsets can be stored.

Then, in the tracking mode, the cascade of input offset storage stages 321 to 32N, the second output offset storage stage 330 and the first output offset storage stage 310 sequentially leave the offset cancellation mode. That is, as shown in FIG. 4, the feedback switches Sf1 to SfN and the input offset storage switches Sios1 to SiosN of the input offset storage stages 321 to 32N, the second output offset storage switches Soos2 and the second switches S2 of the second output offset storage stage 330, and the first output offset storage switches Soos1 of the first output offset storage stage 310 are sequentially off.

Next, the first switches S1 of the first output offset storage stage 310 and the second output offset storage stage 330 are turned on. Thus, the preamplifier 305 amplifies the input voltage Vin. At this time, the input offsets and the output offsets stored in the offset cancellation mode are respectively offset with the offset voltages generated by the low offset comparator 300. Thereafter, in the latching mode, the latch 340 is strobed by the amplified input signal outputted from the preamplifier 305, and outputs the logic level Vout according to the voltage level at the output end of the preamplifier 305.

The low offset comparator according to the embodiment of the invention is substantially formed by multiple amplifiers that are cascaded, and thus has the extremely low carrier injection effect. In addition, the equivalent capacitor at its input end is smaller, and the cascaded amplifiers also make the low offset comparator have the greater gain value, so the low offset comparator can eliminate the offset voltages more effectively. In addition, the first output offset storage stage of the low offset comparator uses a first rail-to-rail amplifier, so the low offset comparator has the larger input range. Compared with the conventional comparator having the same gain value, the low offset comparator of the invention has the higher circuit operation speed and can be widely applied to various comparator circuits due to the cascaded architecture in conjunction with the input offset storage technology and the output offset storage technology.

The invention also provides an offset cancellation method of a comparator. The comparator includes a preamplifier and a latch. The preamplifier includes a first output offset storage stage for receiving an input voltage, a cascade of input offset storage stages and a second output offset storage stage. The cascade of input offset storage stages is connected to follow the first output offset storage stage, and the second output offset storage stage is connected to follow the input offset storage stages. The latch is connected to follow the preamplifier.

First, the cascade of input offset storage stages, the second output offset storage stage and the first output offset storage stage are configured to sequentially leave an offset cancellation mode. Next, when leaving the offset cancellation mode, the input offset storage stages opening their unity-gain feedback loops before disconnecting their input offset storages from a ground voltage. Then the preamplifier amplifies the input voltage in a tracking mode. Afterwards, the latch is strobed by the amplified input voltage and outputs a logic level accordingly in a latching mode.

The detailed operation principles of the offset cancellation method of a comparator disclosed in the invention has described in the low offset comparator 300, and thus is omitted hereinafter.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A low offset comparator, comprising:
a preamplifier, comprising:
a first output offset storage stage for receiving an input voltage;
a cascade of input offset storage stages connected to follow the first output offset storage stage; and
a second output offset storage stage connected to follow the input offset storage stages; and
a latch connected to follow the preamplifier;
characterized in that,
the cascade of input offset storage stages, the second output offset storage stage and the first output offset storage stage are configured to sequentially leave an offset cancellation mode, and the input offset storage stages, when leaving the offset cancellation mode, are to open their unity-gain feedback loops before disconnecting their input offset storages from a ground voltage.

2. The low offset comparator according to claim 1, wherein in the offset cancellation mode, each of the input offset storage stages stores its input offset to its input offset storage, and the second output offset storage stage and the first output offset storage stage respectively store their output offsets to their output offset storages.

3. The low offset comparator according to claim 1, wherein after the cascade of input offset storage stages, the second output offset storage stage and the first output offset storage stage sequentially leave the offset cancellation mode, the preamplifier amplifies the input voltage in a tracking mode.

4. The low offset comparator according to claim 3, wherein in a latching mode, the latch is strobed by the amplified input voltage and outputs a logic level accordingly.

5. The low offset comparator according to claim 1, wherein the first output offset storage stage comprises:
a first rail-to-rail amplifier having two input ends and two output ends;
two first output offset storages each having a first end coupled to the corresponding output end of the first rail-to-rail amplifier;
two first output offset storage switches each having a first end coupled to the ground voltage, and a second end coupled to the corresponding input end of the first rail-to-rail amplifier; and
two first switches having first ends for receiving the input voltage, and second ends respectively coupled to the input ends of the first rail-to-rail amplifier;
wherein in the offset cancellation mode, the first switches are off and the first output offset storage switches are turned on.

6. The low offset comparator according to claim 5, wherein after the cascade of input offset storage stages, the second output offset storage stage and the first output offset storage stage sequentially leave the offset cancellation mode, the first switches are on and the first output offset storage switches are off in a tracking mode.

7. The low offset comparator according to claim 1, wherein the input offset storage stages respectively comprise:
an amplifier having two input ends and two output ends;
two input offset storages each having a second end coupled to the corresponding input end of the amplifier;
two feedback switches each having a first end coupled to the corresponding input end of the amplifier, and a second end coupled to the corresponding output end of the amplifier; and
two input offset storage switches each having a first end coupled to the ground voltage, and a second end coupled to the first end of the corresponding input offset storage:
wherein in the offset cancellation mode, the input offset storage switches and the feedback switches are sequentially turned on.

8. The low offset comparator according to claim 7, wherein after the cascade of input offset storage stages, the second output offset storage stage and the first output offset storage stage sequentially leave the offset cancellation mode, the input offset storage switches and the feedback switches are off in a tracking mode.

9. The low offset comparator according to claim 1, wherein the second output offset storage stage comprises:
a second rail-to-rail amplifier having two input ends and two output ends;
two second output offset storages each having a first end coupled to the corresponding output end of the second rail-to-rail amplifier, and a second end coupled to the latch;
two second output offset storage switches each having a first end coupled to the ground voltage, and a second end coupled to the corresponding input end of the second rail-to-rail amplifier;
two first switches each having a first end coupled to the last stage of the input offset storage stages, and a second end coupled to the corresponding input end of the second rail-to-rail amplifier; and
two second switches each having a first end coupled to the ground voltage, and a second end coupled to the latch:
wherein in the offset cancellation mode, the first switches are off, and the second output offset storage switches and the second switches are turned on.

10. The low offset comparator according to claim 9, wherein after the cascade of input offset storage stages, the second output offset storage stage and the first output offset storage stage sequentially leave the offset cancellation mode, the first switches are on and the second output offset storage switches and the second switches are off in a tracking mode.

11. An offset cancellation method of a comparator, which comprising a preamplifier that comprises a first output offset storage stage for receiving an input voltage, a cascade of input offset storage stages and a second output offset storage stage, the method comprising:
configuring the cascade of input offset storage stages, the second output offset storage stage and the first output offset storage stage to sequentially leave an offset cancellation mode; and
when leaving the offset cancellation mode, the input offset storage stages opening their unity-gain feedback loops before disconnecting their input offset storages from a ground voltage.

12. The offset cancellation method according to claim 11, wherein the cascade of input offset storage stages are connected to follow the first output offset storage stage, and the second output offset storage stage is connected to follow the input offset storage stages.

13. The offset cancellation method according to claim 11, wherein in the offset cancellation mode, each of the input offset storage stages stores its input offset to its input offset storage, and the second output offset storage stage and the first output offset storage stage respectively store their output offsets to their output offset storages.

14. The offset cancellation method according to claim 11, wherein after the cascade of input offset storage stages, the second output offset storage stage and the first output offset storage stage sequentially leave the offset cancellation mode, the preamplifier amplifies the input voltage in a tracking mode.

15. The offset cancellation method according to claim 14, wherein the comparator further comprises a latch connected to follow the preamplifier, and the latch is strobed by the amplified input voltage and outputs a logic level accordingly in a latching mode.
